(19) United States
(12) Patent Application Publication
(10) Pub. No.: US 2005/0149798 A1
(43) Pub. Date: Jul. 7, 2005

(54) Semiconductor integrated circuit

(75) Inventors: Kohtaro Inuzuka, Minato-ku (JP); Junichi Tamura, Minato-ku (JP); Hiroki Goko, Minato-ku (JP); Osamu Endoh, Minato-ku (JP)

Correspondence Address: SHINJYU GLOBAL IP COUNSELORS, LLP, 1233 20TH STREET, NW, SUITE 700, WASHINGTON, DC, 20036-2680, US

(73) Assignee: Oki Electric Industry Co., Ltd., Minato-ku (JP)

(21) Appl. No.: 10/999,976

(22) Filed: Dec. 1, 2004

(30) Foreign Application Priority Data
Dec. 1, 2003 (JP) JP 2003-401411
Oct. 21, 2004 (JP) JP 2004-307234

(51) Int. Cl. G01R 31/28

(52) U.S. Cl. 714/726

(57) ABSTRACT

The present invention provides a LSI being capable of testing a signal path between two circuit blocks by a scan isolation test. A scan isolation circuit 30-1 includes a first selector 31 alternating a held signal S33 or a signal SA from circuit block 10A and outputting the alternated signal thereof as signals 31, and a second selector 32 selecting the signal S31 or one signal from the signal SAm from outside or the previous-stage signal S33. Further, the held signal S33 held in the FF 33 thereof is supplied to the selector 31 and the next-stage scan isolation circuit 30-2, connecting the FF 33 to the output terminal. During the test therein, since the signal SA is held through the selectors 31 and 32, the signal path between the circuit blocks 10A and 10B can be conducted.

### BACKGROUND OF THE INVENTION

1. Field of the Invention

The present invention generally relates to a semiconductor integrated circuit. More specifically, the present invention relates to a semiconductor integrated circuit having a scan test function.

2. Background Information

Japanese Patent Publication No. 2002-2963232 discloses a circuit and method for a scan test. Japanese Patent Publication No. H6-102316 discloses a scan path flip-flop. Japanese Patent Publication No. 2002-310671discloses a navigation apparatus. Japanese Patent Publication No. 2000-310671 discloses a scan flip-flop. Japanese Patent Publication No. 2003-344504 discloses a scan flip-flop circuit, scan flip-flop circuit array, and integrated circuit device. The entire disclosure of Japanese Patent Publication Nos. 2002-2963232, H6-102316, 2002-310671, 2000-310671, and 2003-344504 are hereby incorporated by reference.

Among large scale integrated circuits (referred to as LSIs hereinafter) having complicated functions, LSIs with built-in test circuits (scan paths and scan-path registers) are generally used for screening tests in production lines.

FIG. 2 is a schematic diagram illustrating the configuration of an LSI having a scan-path register. The LSI includes an input-side combinational circuit 1A, an intermediate combinational circuit 1B, and an output-side combinational circuit 1C. The input-side combinational circuit IA outputs intermediate signals SA1-SAm, when given an input data DI₁-DI₁ by an input terminal. The intermediate combinational circuit 1B outputs intermediate signals SB₁-SBn when given the intermediate signals S2₁-2m. The output-side combinational circuit IC outputs output data DO₁-DO_{y} when given intermediate signals S3₁-S₃. At the same time, m lines of signal between the combinational circuit 1A and the combinational circuit 1B are connected to each other through scan-path registers (SPR) 2-1 to 2-m. Further, n lines of signal between the combinational circuit 1B and the combinational circuit 1C are connected to each other through scan path registers 3-1 to 3-n.

Each scan path register 2-1 to 2-m and 3-1 to 3-n has the same circuit configuration. Each scan path register is made of a selector selecting a first signal or a second signal and a flip-flop (referred to as FF hereinafter) holding and outputting according to a clock a signal selected by the selector thereof.

The scan path register 2-1 is composed so that the intermediate signal SA1 can be inputted into a first input terminal of the selector from the combinational circuit 1A. The scan path register 2-1 has a second input terminal that can be given a signal Sin connected to an input terminal thereof. Further, an output signal from an FF of the scan path register 2-1 can be inputted to a combinational circuit 1B as the intermediate signal S2₁, and also can be given to the second input terminal of the scan path register 2-2 at a subsequent stage through a scan path thereof.

Similarly, a first input terminal of the scan path register 2-i (where i=2-m) can be inputted with the intermediate signal SAi from the combinational circuit IA and the second input terminal thereof can be given the intermediate signal S2i-1 from the FF of scan path register 2(i-1) at the previous stage.

At the same time, the scan path register 3-1 is composed so that a first input terminal of a selector thereof can be given the intermediate signal SB 1 from the combinational circuit 1B, and a second input terminal of the selector thereof can be given the intermediate signal S2m from the FF of the scan path register 2-m. Furthermore, a first input terminal of the selector of the scan path register 3-j (where, j=2-n) can be given the intermediate signal SBj, and a second input terminal of this selector can be inputted with the intermediate signal S2j-1 from the FF of the scan path register 3-(j-1).

Furthermore, the output terminal of the FF of the scan path register 3-n can be connected to an output terminal and output a signal Sout.

An LSI having the aforementioned scan path registers can be subjected to a screening test in the production line based on a procedure explained below.

(1) Serial Input Operation

All the selectors of the scan path registers 2-1 to 2-m and the scan path registers 3-1 to 3-n are switched to the second input terminal therein by a control signal not shown in the drawing. By this operation, each output terminal of all the scan path registers 2-1 to 2-m and the the scan path registers 3-1 to 3-n is connected to the input terminal of the following one, forming a m+n stage shift-register. Where, each FF of the the scan path registers 2-1 to 2-m and the the scan path registers 3-1 to 3-n is given a common clock signal and each input terminal thereof is serially inputted with a test pattern signal Sin synchronized with the clock signal. Subsequently, the test pattern signal is held in the scan path register 2-1 to 2-m and the scan path register 3-1 to 3-n.

(2) Parallel Signal Operation

The test pattern signal held therein is given to the combinational circuit 1B and 1C as a test signal. At the same time, the input terminals of the combinational circuit 1A are given in parallel test pattern signals as input data DI₁-DIₓ. Further, the signals according to the test pattern signals are outputted in parallel from each output terminal of the combinational circuits 1A, 1B, and 1C.

At this moment, all selectors are switched to the first input terminals of the scan path registers 2-1 to 2-m and the scan path registers 3-1 to 3-n, and the first input terminals are connected to the input terminals of the corresponding FFs. Further, a common clock signal is inputted to each FF thereof and then each parallel output from the combinational circuit 1A and 1B is held on the corresponding FF. At the same time, the output signals from the combinational circuit 1C are outputted in parallel from the external terminals as the output data DO₁-Do_{y}.

(3) Serial Output Operation

After the parallel output from the combinational circuits 1A and 1B is held in the corresponding FF, the m+n stage register is formed by switching selectors of the scan path registers 2-1 to 2-m and the scan path registers 3-1 to 3-n to the second input terminals again. Further, a common clock signal is inputted to each FF of the scan path registers 2-1 to 2-m and the scan path registers 3-1 to 3-n. Subsequently, the data held in each FF of the scan path registers 2-1 to 2-mand the scan path registers 3-1 to 3-n are outputted serially from a scan-path output terminal synchronized with the common clock signal.

(4) Comparing and Judging Operation

The comparison is made between the anticipated output data pattern according to the predetermined test pattern data, the serial output outputted by the real serial output operation therein, and the output data DO₁-DO_{y} according to the aforementioned article (2). When the real output data match the anticipated data, the function corresponding to the test data pattern is judged to be normal. Preparing a plurality of test data according to the functions under testing, the LSI is judged to be normal when each output datum matches each anticipated datum corresponding to all test data thereof.

When a functional test is done with the aforementioned test circuits, the test data pattern corresponding to the functional test and the corresponding anticipated data pattern should be prepared using in advance a specific circuit configuration information such as a net list and so on.

When a company produces an LSI having a certain built-in combinational circuit being licensed by another company, however, the information of the certain combinational circuit may not be able to be acquired. In this case, a scan isolation block is built to conduct the test, separating certain combinational circuits from other combinational circuits.

FIG. 3 is a schematic configuration diagram of an LSI having a conventional scan isolation block. The LSI is made of circuit blocks 10A and 10B, and a plurality of scan isolation circuits 20-1 to 20-n, where each scan isolation circuit is built for a corresponding signal among the signals SA1-SAn connecting the circuit blocks 10A and 10B. Each scan isolation circuit 20-1 to 20-n has the same configuration and is composed of three selectors 21, 22, and 23 and one FF 24.

For example, the signal SA1 from the circuit block 10A is given to the input terminal A of the selector 21 and the signal S2₁ is outputted from an output terminal of the selector 21 to the circuit block 10B in the scan isolation circuit 20-1. An output terminal of the selector 22 is connected to the input terminal B of the selector 23. The input terminal A of the selector 23 is given the serial signal Sin from a scan input terminal not shown in the diagram. An output terminal of the selector 23 is connected to the input terminal of the FF 24. An output terminal of the FF 24 is connected to the input terminal B of the selector 21. Further, a serial signal from the output terminal of the FF 24 is given to an input terminal A of the selector 23 of the scan isolation circuit 20-2 at the next stage.

Further, an output terminal of the FF 24 of the scan isolation circuit 20-n at the final stage is connected to the input terminal B of the selector 21. Further, the serial signal Sout is outputted from the scan output terminal.

The LSI having the aforementioned scan isolation block is tested as described below, except for the normal operation switching for each of the selectors 21 to the input terminals A.

(1) Test for the Circuit Block 10A

Test pattern data are given to an input terminal not shown in the diagram from the aforementioned parallel input terminal or a scan path register. At the same time, the selectors 22 and 23 of the scan isolation circuits 20-1 to 20-n are respectively switched to the input terminals A and input terminals B. During this operation, the signals SA1 to SAn from the circuit block 10A are inputted to the input terminal D of the FF 24 of each scan isolation circuit 20-1 to 20-n. In this situation, each signal SA1 to SAn is held in the corresponding FF 24, and a common clock signal is given to each FF 24.

Furthermore, the selector 23 of each scan isolation circuit 20-1 to 20-n is switched to the respective input terminal A. Consequently, the output terminal of the FF 24 of each scan isolation circuit 20-2 to 20-n is respectively connected to the input terminal of the following selector 23, and then an n-stage shift register is composed. Further, the data held in the FF 24 of each scan isolation circuit 20-1 to 20-n with the common clock signal inputted are synchronously outputted with the common clock signal from the scan output terminal thereof as the serial signal Sout.

Whether the circuit block 10A works normally or not is determined by the comparison between the anticipated output data from the circuit block 10A according to a test pattern data and the data outputted as the real serial data Sout.

(2) Test for the circuit block 10A

First, the selectors of each scan isolation circuit 20-1 to 20-n are switched to the input terminals A. Then, the output terminals of each FF 24 are respectively connected to the input terminals of the following selector 23, and an n-stage shift register is composed. Further, a common clock signal is given to the FF 24 of each scan isolation circuit 20-1 to 20-n, and the serial signal Sin of the test pattern data is synchronously inputted with the common clock signal from an input terminal. Consequently, the test pattern data are held in the FF 24 of each scan isolation circuit 20-1 to 20-n.

Furthemore, the selectors 21, 22, and 23 of each scan isolation circuit 20-2 to 20-n are switched to the input terminals B, and then the test pattern data held in each FF 24 are given to the input terminal of the circuit block 10B.

The parallel output signal according to the test pattern data from the output terminal of the circuit block 10B not shown in the drawing is read by the aforementioned parallel output terminal or the scan path register. Then, whether the circuit block 10B works normally or not is decided by the comparison between the anticipated output data from the circuit block 10B according to the test pattern data and the real output data.

However, during the test for the circuit blocks 10A and 10B of the LSI having the conventional scan isolation circuits 20-1 to 20-n, the test for the signal paths through the input terminals A of the selectors 21 of the scan isolation circuits 20-1 to 20-n is not done. For this reason, any defects of the signal path through the input terminal A of the selector 21 of the scan isolation circuits 20-1 to 20-n cannot be found, and the LSI may not work normally after being judged to work normally and installed into some equipment or system.

Furthermore, when a clock skew occurs between the FF in each scan isolation circuit 20-1 to 20-n and the FF in the circuit blocks 10A and 10B, a countermeasure to hold the data properly is necessary. A buffer circuit for the holding of the data is inserted into the signal path of the normal operation of the scan isolation circuits, depending upon the situation. Consequently, a problem in which the power consumption of the normal operation will increase and the operation speed decrease occurs.

In view of the above, it will be apparent to those skilled in the art from this disclosure that there exists a need for an improved semiconductor integrated circuit. This invention addresses this need in the art as well as other needs, which will become apparent to those skilled in the art from this disclosure.

### SUMMARY OF THE INVENTION

The present invention provides a first holding circuit, a first selector, a first circuit block, a second circuit block and a scan isolation block. The first circuit block has a scan isolation block of an LSI that includes the first circuit block. The scan isolation block transmits signals between the first circuit block and the second circuit block during normal operation and isolates the connection between the first circuit block and the second circuit block during a test operation. The first holding circuit synchronously with the clock signal holds the data thereof. The first selector selects one signal from the output signals of the first circuit block output or the first test signal from the first holding circuit thereof. The first selector is inserted between the second circuit block and the first holding circuit thereof. The output from the first selector is inputted to the first holding circuit thereof.

The Effect of the Present Invention

Since the LSI according to the present invention includes the scan isolation circuit having the holding circuit holding the signal being selected by the selector and outputted to the other circuit block, the signal path from one circuit block to another circuit block can be tested by the scan test.

These and other objects, features, aspects, and advantages of the present invention will become apparent to those skilled in the art from the following detailed description, which, taken in conjunction with the annexed drawings, discloses a preferred embodiment of the present invention.

### BRIEF DESCRIPTION OF THE DRAWINGS

Referring now to the attached drawings which form a part of this original disclosure:

FIG. 1 is a view of a schematic configuration diagram of an LSI having scan isolation circuits register in accordance with a first embodiment of the present invention;

FIG. 2 is a view of a schematic configuration diagram of an LSI having one scan path register;

FIG. 3 is a view of a schematic configuration diagram of an LSI having a conventional scan isolation circuit;

FIG. 4(a) is a view of an explanatory diagram illustrating a circuit configuration of a test circuit in accordance with a second embodiment of the present invention;

FIG. 4(b) is a view of a table illustrating the relationship between an input signal and an output signal of a control unit of the test circuit of FIG. 4(a);

FIG. 5 is a view of a configuration diagram of an LSI having the test circuit of FIG. 4(a);

FIGS. 6(a) and 6(b) are views of timing charts illustrating operations of a test of the test circuit of FIG. 4(a).

FIGS. 7(a) and 7(b) are views of configuration diagrams of scan isolation circuits in accordance with a third embodiment of the present invention;

FIG. 8 is a view of a configuration diagram of a test circuit in accordance with the fourth embodiment of the present invention; and

FIG. 9 is a view of a timing chart illustrating an operation of a test of the test circuit of FIG. 8.

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

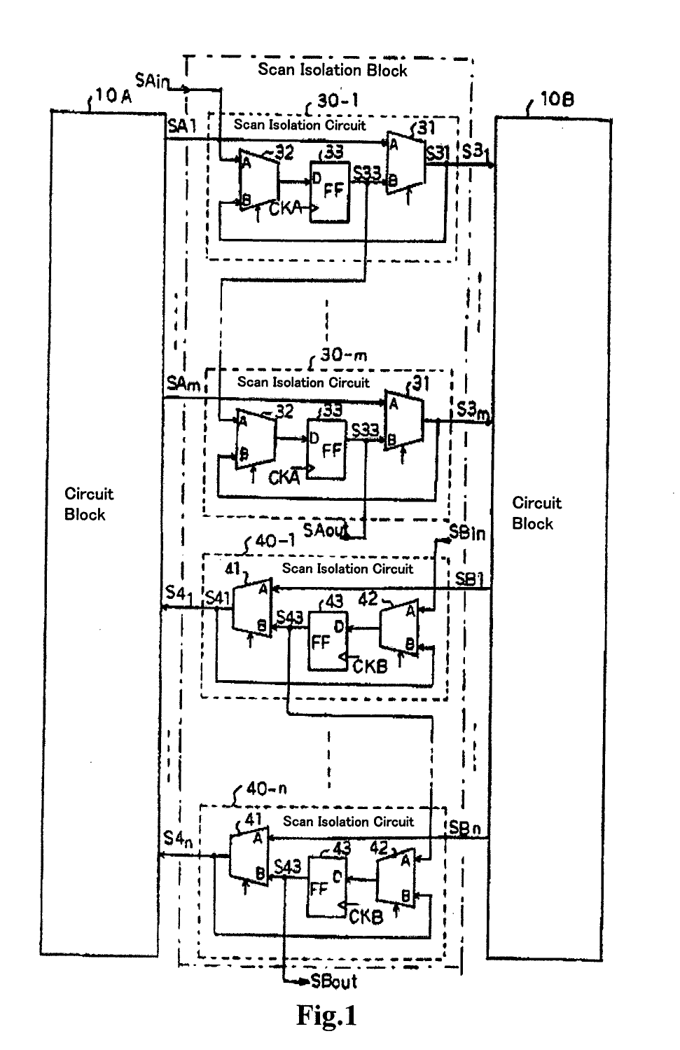

Referring initially to FIG. 1, scan isolation circuits 30-1 to 30-m and 40-1 to 40-n are inserted in a signal path between circuit blocks 10A and 10B. The scan isolation circuits 30-1 to 30-m and 40-1 to 40-n connect signal paths between the circuit blocks 10A and 10B during the normal operation thereof, and isolate signal paths between the circuit blocks 10A and 10B during the test operation thereof. The scan isolation circuits are configured as described below.

Specifically, each scan isolation circuit 30-1 to 30-m or 40-1 to 40-n includes a first selector 31 or 41 and a second selector 32 or 42. The first selector 31 or 41 selects the output signal from the circuit block 10A or the circuit block 10B, or the signal held for the test, and transmits the selected signal to the other circuit block after selecting thereby. The second selector 32 or 42 selects one signal out of the test data from an external terminal, the held signal from the scan isolation circuit at the previous stage, or the output signal from the first selector 31 or 41. Furthermore, the scan isolation circuit 30-1 to 30-m or 40-1 to 40-n includes a holding circuit that holds the output signal from the second selector 32 or 42 according to the clock signal, and gives the held signal to the first selector 31 or 41. Further, the scan isolation circuit 30-1 to 30-m or 40-1 to 40-n outputs the held signal to the second selector 32 or 42 or the external terminal of the scan isolation circuit 30-1 to 30-m or 40-1 to 40-n at a subsequent stage.

FIG. 1 is a view of a schematic configuration diagram of an LSI according to a first preferred embodiment of the present invention. The LS I includes the circuit blocks 10A and 10B and a scan isolation block that connects the circuit blocks 10A and 10B. The scan isolation block is made of a plurality of first scan isolation circuits 30-1 to 30-m, with each circuit thereof corresponding to each signal SA1-SAm from the circuit block 10A to the circuit block 10B. The scan isolation block also includes a plurality of second scan isolation circuits 40-1 to 40-n with each circuit thereof corresponding to each signal S4₁-S4ₙ from the circuit block 10A to the circuit block 10B.

Each first scan isolation circuit 30-1 to 30-m preferably has the same configuration, and is made of the two selectors 31 and 32 and one FF 33. For example, the first scan isolation circuit 30-1 is composed so that the signal SA1 from the circuit block 10A can be given to the input terminal A of the first selector 31. Further, the signal S31 can be outputted from the output terminal of the first selector 31 to the circuit block 10B. Moreover, the signal S31 can be given to the input terminal B of the second selector 32, and the input terminal A of the second selector 32 can be given the serial signal SAin from a scan input terminal. The output terminal of the FF 33 can be connected to the input terminal B of the first selector 31, and also can be connected to the input terminal A of the second selector 32 of the first scan isolation circuit 30-2, thus, inputting a serial signal therein.

Furthermore, the output terminal of the FF 33 of the first scan isolation circuit 30-m at the final stage can be connected to the input terminal B of the first selector 31 of the first scan isolation circuit 30-m, and also can be connected to the scan output terminal and can output the serial signal SAout.

Each second scan isolation circuit 40-1 to 40-n has the same or similar circuit configuration as the first scan isolation circuits 30-1 to 30-m, including two selectors 41 and 42 and one FF 43, save one major difference; the second scan isolation circuits 40-1 to 40-n are arranged in a mirror image fashion compared to the first scan isolation circuits 30-1 to 30-m and relative to the circuit blocks 10A and 10B. Each second scan isolation circuit 40-1 to 40-n is composed so that the output terminal of each scan circuit can be respectively connected to the input terminal of the following one, as in the case of the first scan isolation circuits 30-1 to 30-m. Further, the first-stage second scan isolation circuit 40-1 can be given the serial signal SBin from the scan input terminal and the final-stage scan isolation circuit 40-n can be connected to the output terminal and output the serial signal SBout.

An operation of the aforementioned LSI having the scan isolation block will be explained as below.

(1) Normal Operation

The first selector 31 of each first scan isolation circuit 30-1 to 30-m and the first selector 41 of each second scan isolation circuit 40-1 to 40-n are switched to the input terminal A. By the switching, each signal SA1-SAm is given to the circuit block 10B as the signal S3₁-S3ₘ through the first selector 31 of each first scan isolation circuit 30-1 to 30-m. At the same time, each signal SB1-SBn is given to the circuit block 10A as the signal S4₁-S4ₙ through the first selector 41 of each second scan isolation circuit 40-1 to 40-n.

(2) Test For The Circuit Block 10A

The test pattern is given to the input terminal of the circuit block 10A, not shown in the drawings. At the same time, the selectors 41 and 42 of each second scan isolation circuit 40-1 to 40-n are switched to the input terminal A. By this switching, the output terminal of the FF 43 of each second scan isolation circuit 40-1 to 40-n is respectively connected to the input terminal of the following second selector 42 and then an n stage shift register is formed. Further, the common clock signal CKB is inputted to the FF 43 of each second scan isolation circuit 40-1 to 40-n and at the same time the serial signal SBin of the test pattern data is inputted to the scan input terminal A of the second selector 42 of the first stage second scan isolation circuit 40-1. The test pattern data have been synchronized with the clock signal CKB. By the operation, the test pattern data are held on the FF 43 of each second scan isolation circuit 40-1 to 40-n.

Test pattern data are inputted to the input terminal not shown in the drawings. At the same time, the second selector 42 of each second scan isolation circuit 40-1 to 40-n is switched to the input terminal A.

Secondly, the selectors 41 and 42 of each second scan isolation circuit 40-1 to 40-n are switched to the input terminal B. By this operation, the test pattern data held in each FF 43 are given to the circuit block 10A in parallel through the first selector 41.

Subsequently, the operation of the circuit block 10A is based on the signal given to all the input terminals, and the signals SA1-SAm are outputted and the output signals are outputted from the output terminals not shown in the drawings.

After this operation, the selectors 31 and 32 of each first scan isolation circuit 30-1 to 30-m are respectively switched to the input terminals A and B. By this switching, the output signals SA1-SAm from the circuit block 10A are given to the input terminal D of the FF 33 through the selectors 31 and 32 of each scan isolation circuit 30-1 to 30-m. In this situation, the signals SA1-SAm are held in the FF 33 of the corresponding scan isolation circuits 30-1 to 30-m, giving the common clock signal CKA to each FF 33.

Secondly, the second selector 32 of each first scan isolation circuit 30-1 to 30-m is switched to the input terminal A. The output terminal of the FF 33 is respectively connected to the input terminal A of the following second selector 32 and an m stage shift register is formed. Then, the FF 33 of each first scan isolation circuit 30-1 to 30-m is given the common clock signal CKA. Consequently, the data held in the FF 33 are outputted from the scan output terminal as the serial signal SAout. Further, the data have been synchronized with the clock signal CKA.

The comparison is made between the anticipated output data from the circuit block 10A according to the test pattern data and the real output data as the serial signal SAout, and then is judged whether the operation of is normal or not.

(3)Test for the circuit block 10B

The circuit block 10B is symmetric to the circuit block 10A. Then, converse to the explanation of the article (2), whether the function of the circuit block 10B is normal or not can be judged by the inputting of the test pattern data from each first scan isolation circuit 30-1 to 30-m as the serial SAin and reading out the output signal SB1-SBn as the serial signal SBout by each scan isolation SB1-SBn.

As explained before, each scan isolation circuit 30-i (40-1) according to the first embodiment of the present invention includes the first selector 31 (41), the second selector 32 (42), and the FF 33 (43). The first selector 31(41) switches the output signal SAi (SBi) from the circuit block 10A (10B) and the test signal, giving it to the circuit block 10A (10B). The second selector 32 (42) switches the output signal from the second selector 32 (42) with the serial test signal. The FF 33 (43) holds the output signal from the second selector 32 (42) and gives the output signal held therein to the aforementioned first selector 31 (41) and also outputs the output signal held therein as the serial test data. With these circuits, the signals through all the signal paths can be tested in the test for the circuit blocks 10A and 10B. Thus, there is less possibility that an LSI function error will be detected after the installation of the LSI to the device due to the lack of the signal path tests thereof.

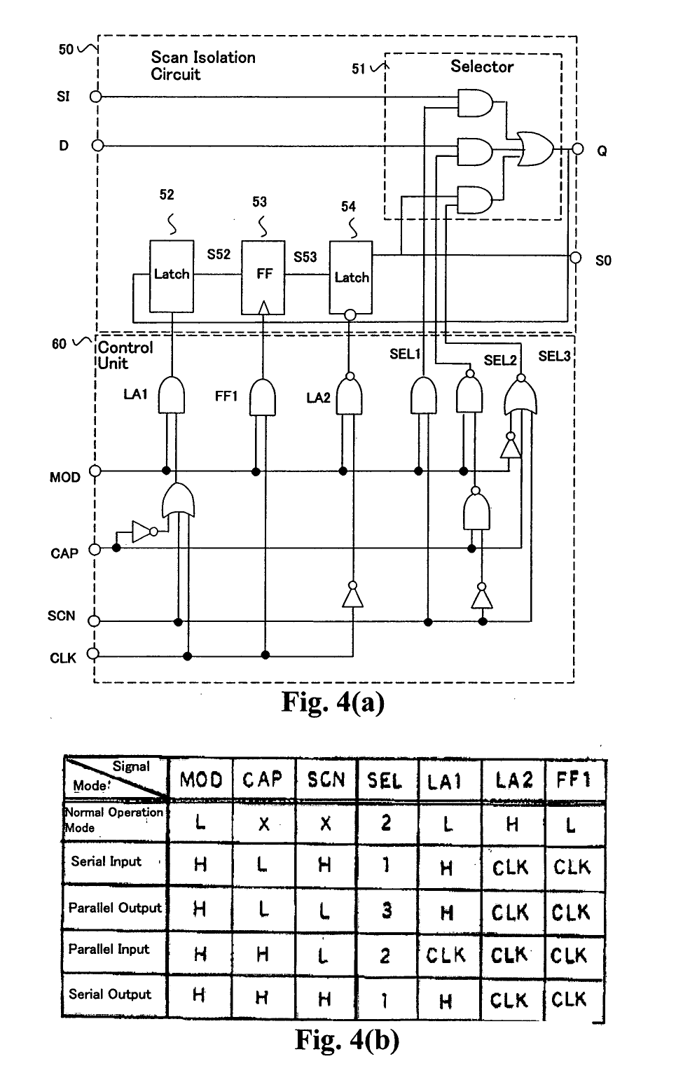

Further, since the number of selectors of the scan isolation circuits 30 and 40 is one smaller than the scan isolation circuit in the FIG. 3, the circuit pattern areas can be reduced by about 10%.

Furthermore, the scan isolation circuits with the aforementioned circuit configuration are applicable to a scan isolation circuit having an expanded function, such as outputting test pattern data to circuit blocks thereof, masking the part of the test pattern data.

As used herein, the following directional terms “forward, rearward, above, downward, vertical, horizontal, below, and transverse” as well as any other similar directional terms refer to those directions of a device equipped with the present invention. Accordingly, these terms, as utilized to describe the present invention should be interpreted relative to a device equipped with the present invention.

### Alternate Embodiments

Alternate embodiments will now be explained. In view of the similarity between the first and alternate embodiments, the parts of the alternate embodiment that are identical to the parts of the first embodiment will be given the same reference numerals as the parts of the first embodiment. Moreover, the descriptions of the parts of the alternate embodiments that are identical to the parts of the first embodiment may be omitted for the sake of brevity.

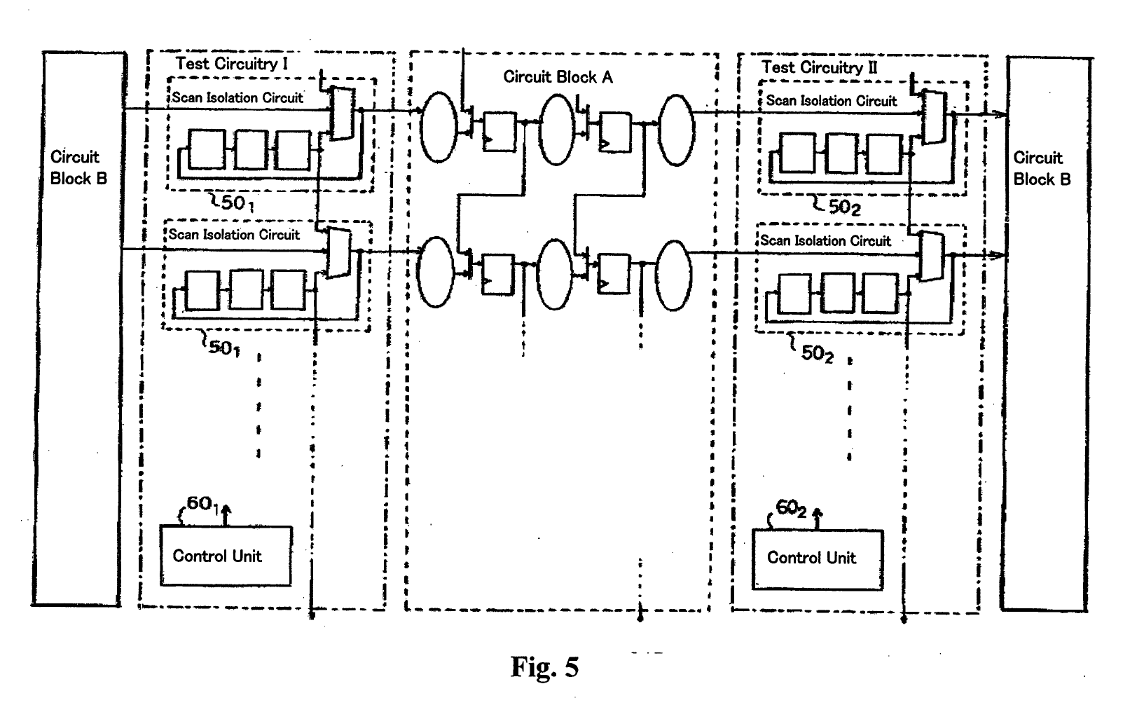

FIGS. 4(a) and 4(b) are views of a circuit configuration and signal relationship table of a test circuit according to a second preferred embodiment of the present invention. FIG. 4(a) is a view of the circuit configuration of the test circuit, and FIG. 4(b) is a view of a table illustrating the relationship between the input signal of a control unit 60 at each operational mode and the output signal. The test circuit therein is made of a scan isolation circuit 50 for signals of circuit blocks thereof and a control unit 60 giving a common control signals to at least one scan isolation circuit 50 for signals of the circuit block.

The scan isolation circuit 50 is composed of a selector 51, first and second latches 52 and 54, and a FF 53. The selector 51 selects a signal from a scan input terminal SI given a third test signal, an input terminal D given a signal from a previous-stage circuit block, or the second latch 54, according to a selection signal SEL1, SEL2, or SEL3, and outputs the selected signal thereby. Further, an output terminal of the selector 51 is connected to an input terminal of the first latch 52, and an output terminal of the first latch 52 is connected to an input terminal of the FF 53. An output terminal of the FF 53 is connected to an input terminal of the second latch 54, and an output terminal of the second latch 54 is connected to a scan output terminal SO and with the selector 51.

The control unit 60 generates the selection signals SEL1-SEL3 controlling the selector 51 of the scan isolation circuit 50, signals LA1 and LA2 respectively controlling the latches 53 and 54, and a signal FFI given to a clock terminal of the FF 53, according to a mode signal MOD, a scan control signal SCN, a capture signal CAP, and clock signal CLK.

The first latch 52 holds and outputs a signal of the input terminal when the signal LA1 is H, and outputs the held signal independent of the signal of the input terminal when the signal LA1 changes to L. Contrary to the first latch 52, the second latch 54 is composed to hold and to output a signal of the input terminal when the signal LA2 is L, and outputs the held signal independent of the signal of the input terminal when the signal LA2 changes to H. At the same time, the FF 53 outputs holds and outputs the signal of the input terminal thereof at the rising edge from L to H of the signal FF1.

The mode signal MOD switches an operation mode between a normal operation mode or a test mode. The signal is set to L for the normal mode and is set to H for the test mode. Further, the scan control signal SCN directs whether an serial input and output operation or a parallel input and output operation is done for the test mode, and is set to H for the serial operation thereof. The capture signal directs whether the test pattern is outputted to the circuit block or is inputted from the circuit block, and is set to H in the case of inputting thereof.

The control unit 60, shown in FIG. 4(a), outputs the selection signal SEL2 and also respectively sets the signals LA1, LA2, and FF1 to L, H, and L when the mode signal MOD is set to L so that the normal mode can be directed.

The test mode is directed by setting the mode signal MOD to H and the combination of the capture signal. The scan control signal SCN can direct the serial input operation, the parallel output operation, the parallel input, and the serial output operation.

The serial input operation is directed by setting the capture signal CAP to L and setting the scan control signal SCN to H and then the selection signal SEL1 is outputted and also the signal LA1 is changed to H. At the same time, the clock signal CLK is inputted as the signals LA2 and FF1.

The parallel output operation is directed by setting the capture CAP and setting the scan control signal SCN to L. Further, the selection signal SEL3 is outputted and also the signal LA1 is changed to H. At the same time, the clock signal CLK is outputted as the signals LA2 and FF1.

The parallel input operation is directed by setting the capture signal to H and setting the scan control signal to L. Further, the selection signal SEL2 is outputted and also the clock signal CLK is outputted as the signals LA1, LA2, and FF1.

The serial output operation is directed by setting the capture signal and the scan control signal to H and the selection signal SEL1 is outputted and also the signal LA1 is changed to H. At the same time, the clock signal CLK is outputted as the signals LA2 and FF1.

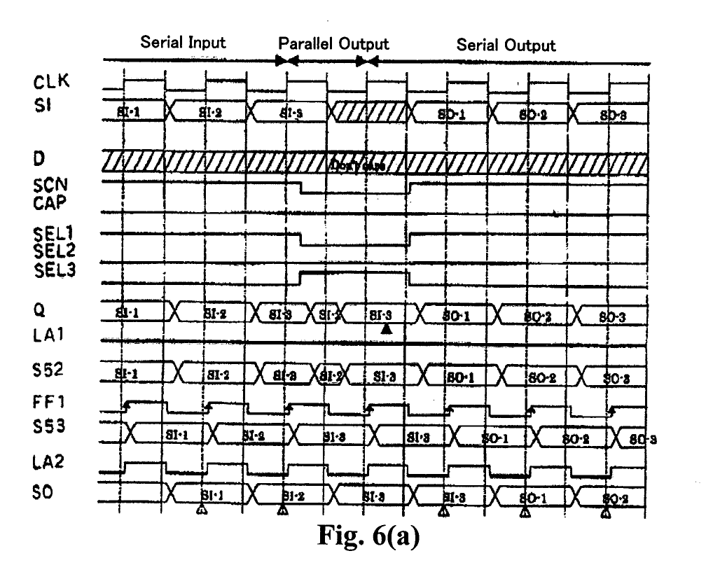

FIG. 5 is a view of a circuit configuration diagram of an LSI having the test function shown in FIG. 4. In this LSI, a test circuit is inserted to the signals connecting between the circuit blocks A and B so that the scan test can be done independently of each other for the circuit block A shown in the center of FIG. 5 and the circuit block B divided and shown respectively in the left and right parts of FIG. 5.

A test circuitry I is made of scan isolation circuits 50₁ and the control unit 60₁. A plurality of scan isolation circuits 50₁ inserted to a plurality of signal paths given from the circuit block B to the circuit block A is given a control signal from the common control unit 60₁. The scan output terminal SO of the scan isolation circuit 50₁ is connected to the scan input terminal SI of the next-stage scan isolation circuit 50₁ so that the test pattern data supplied to the input terminal of the next-stage scan isolation circuit 50₁ can be transferred thereto.

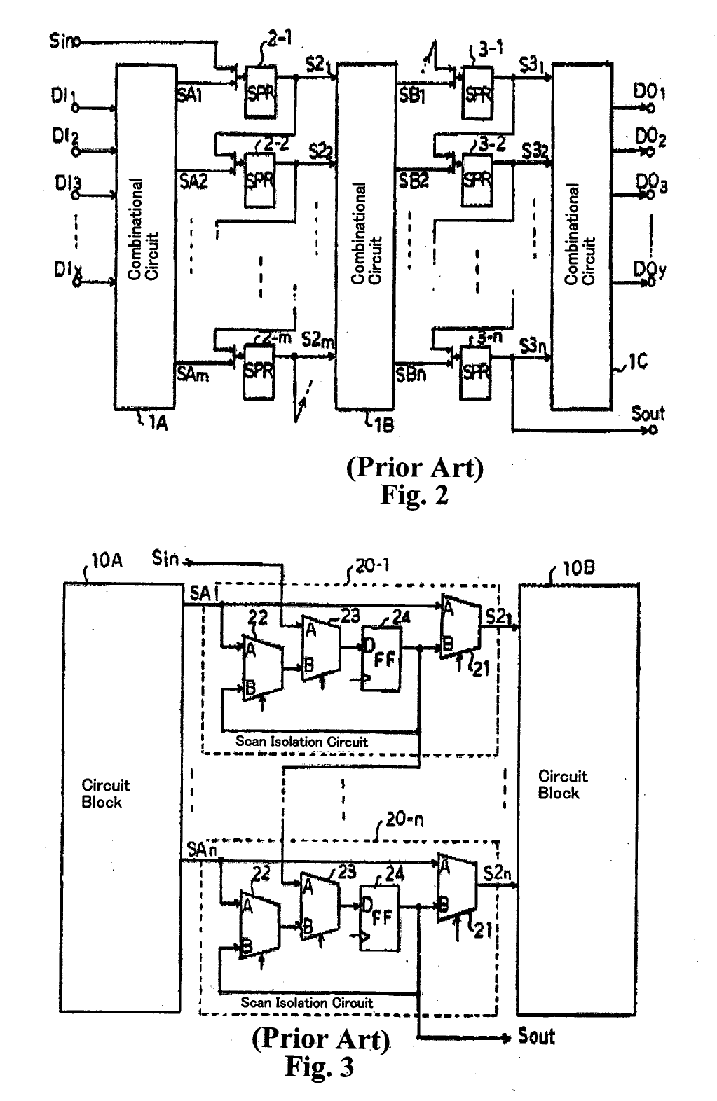

Similarly, a test circuitry II is made of scan isolation circuits 50₂ and a control unit 60₂. The plurality of scan isolation circuits 50₂ inserted to the signal path given from the circuit block A to the circuit block B is given a control signal from the common control unit 60₂. The circuit blocks A and B have a similar circuit configuration to the LSI shown in FIG. 2, and include scan-path registers.

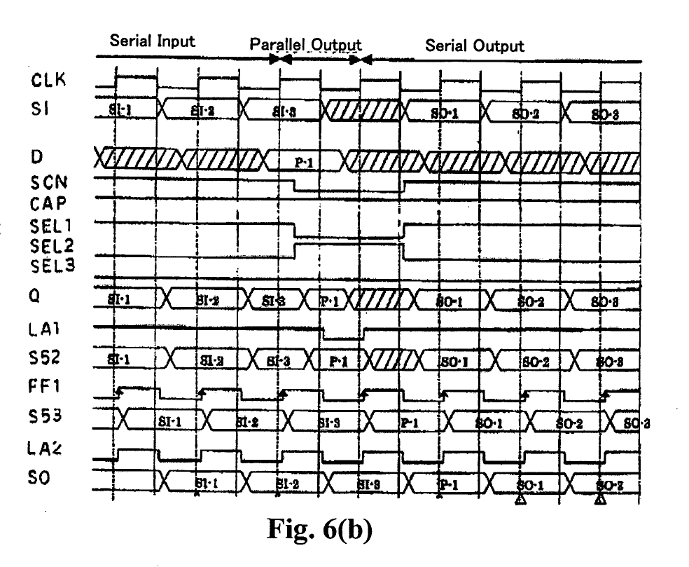

FIGS. 6(a) and 6(b) are views of timing charts illustrating the operation during the test shown FIGS. 4(a) and 4(b). The operation shown in FIGS. 4(a) and 4(b) will be explained below, referring also to FIG. 5 and FIGS. 6(a) and 6(b). The explanation will be done hereinafter, taking the condition that the circuit block A is being tested.

(1) Normal Operation

During normal operations, when the mode signal MOD given to each control unit 60₁ and 60₂ of the test circuitry I and II is set to L, the selection signal SEL2 is outputted, as shown in FIG. 4(b), and the input terminal D is selected in the selector 51 of each scan isolation circuits 50₁ and 50₂. Consequently, the output signal given the input terminal D from the circuit block B is outputted to the circuit block A from the output terminal Q. At the same time, the signals LA1, LA2, and FF1 are respectively fixed to L, H, and L, halting the operations of the latches 52 and 54 and the FF53. By the aforementioned operation, the test circuit does not have any influence over the signal transmission between the circuit blocks A and B.

(2) Serial input operation

During the serial input operation, the test pattern data are inputted serially and saved in the FF 53 of each scan isolation circuit 50₁ of the test circuitry I.

As shown in FIG. 4(b), the selection signal SEL1 is outputted from the control unit 60₁ by setting the capture signal to L and setting the scan control signal to H, and also the signal LA1 is changed to H. At the same time, the clock signal CLK is outputted as the signals LA2 and FF1.

Consequently, shown in the serial input period of FIG. 6(a), the first latch 52 makes the output signal from the selector 51 go through and the FF 53 fetches the output signal S52 from the first latch 52 thereof at the rising edge of the clock signal CLK. Further, the output signal S53 from the FF 53 thereof is delayed by a half period of the clock signal therein by the second latch 54. In the timing chart of FIGS. 6(a) and 6(b), the bold lines of the signals LA1 and LA2 represent the through status thereof and the thin lines represent the hold status thereof and the arrowhead represents the fetching-in data.

During the aforementioned operation, the test pattern supplied from the scan input terminal SI of the scan isolation circuit 50₁ is put through the selector 51 and the first latch 52 and stored in the FF 53. Furthermore, the output signal from the FF 53 is delayed by a half period of the clock by the second latch 54 and outputted from the scan output terminal SO. The same operation is done in the next-stage scan isolation circuit 50₁. As described before, the hold violation can be avoided by delaying the test pattern signal outputted from the scan output terminal SO by a half period of a clock signal thereof.

In parallel with the operation as described before, the circuit block A sets the scan path registers to the scan mode and inputs serially the test pattern data and stores the test pattern data in every FF 53 thereof.

(3) Parallel output operation

During the parallel output operation, the test pattern data stored in the FF 53 of each scan isolation 50₁ of the test circuitry I during the serial input operation are supplied to the circuit block A in parallel.

As shown in FIG. 4(b), when the capture CAP and the scan control signals SCN are set to L, the selection signal SEL3 is outputted from the control 60₁ and also the signal LA1 is turned to H. At the same time, the clock signal CLK is outputted as the signals LA2 and FF1.

Consequently, as shown in the parallel output period of FIG. 4(a), the first latch 52 puts the output signal from the selector 51 through, and the FF 53 fetches the output signal S52 from the latch 52 at the rising edge of the clock signal CLK. Further, the signal S53 is delayed by half a clock period by the second latch 54.

During the aforementioned operation, the test pattern data stored in each scan isolation circuit 50₁ are delayed by a half clock period by the second latch 54, are outputted to the output terminal Q through the selector 51, and are supplied to the input terminal of the circuit block A as test pattern data in parallel.

In the circuit block A, the scan path register is set to the normal mode, and the test pattern data supplied from each scan isolation circuit 501 of the test circuitry I are fetched into the FF 53 in the circuit block A at the rising edge the clock signal thereof. As described before, the hold violation can be avoided during fetching-in to the FF 53 by delaying the test pattern data from the scan output terminal SO of each scan isolation circuit 50₁ by half a clock period. At the same time, the test for the path from the input terminal through the combinational circuit to the FF 53 can be done during the operation described before.

In parallel with the aforementioned operation, the test pattern data stored in the FF 53 within the circuit block A during the serial operation are outputted from each FF 53, and are given to the combinational circuit thereof. Then the output signal from the combinational circuit is saved in the corresponding FF 53. Consequently, the test for the combinational circuit between each FF 53 within the circuit block A can be done.

(4) Parallel Input Operation

During the parallel input operation, the parallel output signal from circuit block A is fetched in the FF 53 of the scan isolation circuit 50₂ of the test circuitry II. Further, the parallel input operation herein is done in parallel with the parallel output operation of the test circuitry I.

As shown in FIG. 4(b), when the capture signal CAP is set to H and the scan control signal SCN is set to L, the selection signal SEL2 is outputted and also the clock signal is outputted as the signals LA1, LA2, and FF1.

Therefore, as shown in the parallel input period of FIG. 6(b), the first latch 52 holds the output signal from the selector 51 during the period when the clock signal CLK is L, and the output signal S52 is fetched in the FF 53 at the rising edge of the clock signal CLK. Further, the output signal S53 is outputted by the second latch 54, delayed by a half period of the clock signal.

During the aforementioned operation, the output signal from the circuit block A is inputted to the terminal D of the scan isolation circuit 50₁ and is stored in the first latch 52 through the selector 51, further the output signal S52 is saved in the FF 53. As shown in the timing charts of FIGS. 6(a) and 6(b), when a clock skew exists between the circuit block A and the FF 53 of the scan isolation circuit 50₁ the output signal from the circuit block A may change before the data fetching in the FF 53 of the scan isolation circuit 50₁ thereof (at the rising edge of the clock signal CLK), causing the hold violation. However, since the scan isolation circuit 50₁ is made so that the signal from the circuit block A can be held before a half period of the clock signal from when the FF 53 fetches in the aforementioned signal by the first latch 52, the hold violation can be avoided. During the operation described before, the test for the path from the FF of the circuit block A to the output terminal through the combinational circuit can be done.

(5) Serial Output Operation

During the serial output operation, the data stored in the FF 53 of the scan isolation circuit 50₂ of the test circuitry II are serially outputted.

As shown in FIG. 4(b), when the capture signal CAP and the scan control signal SCN is set to H, the selection signal SEL1 is outputted from the control unit 60₁ and also the signal LA1 is changed to H. At the same time, the clock signal CLK is outputted as the signals LA2 and FF1.

Consequently, as shown in the serial output period of FIG. 6(b), the latch 52 puts the output signal from the selector 51 through and the output signal S52 from the latch 52 thereof is fetched in the FF 53 at the rising of the clock signal CLK. Furthermore, the output signal S53 from the FF 53 is delayed by a half period of the clock signal thereof by the latch 54.

By the aforementioned operation, the data stored in the FF 53 of the scan isolation 50₂ of the test circuitry II are delayed by a half period clock signal by the latch 54 and are outputted from the output terminal SO. The same operation is done in the next-stage scan isolation circuit 50₂. As described before, the hold violation to the next-stage scan isolation circuit can be avoided.

In parallel with the aforementioned operation, in the circuit block A, the scan path register is set to the scan mode and the data stored in the FF within the circuit block A are serially outputted.

(6) Comparison with the anticipated data.

The comparison between the output data by the serial output operation and the anticipated data is made and then the operation of the combinational circuit is tested. The combinational circuit is judged to be normal when the output data match the anticipated data, and the combinational circuit is judged to be abnormal when the output data do not match to the anticipated.

Although the above explanation is made about a case in which the circuit block A is tested, a case in which the circuit block B is tested can be understandable by respectively altering each function of the test circuitry I or the test circuitry II with the other.

As described before, the test circuit according to the second embodiment of the present invention includes the latches 52 and 54 at the previous stage and the next stage FF 53 to isolate the circuit blocks therein and uses the selector 51 and the control unit 60 to control the circuits thereof. Consequently, even when a clock skew exists between a FF 53 and a next-stage FF 53 within the circuit under test therein, other than the same effect as the first embodiment of the present invention, the additional effect can be achieved as explained below.

(a) When the test data are serially stored in the FF 53 within the test circuit, the hold violation between FF 53 and the next-stage FF 53 can be avoided by delaying the output signal from the FF 53 by a half period of the clock signal thereof by the latch 54.

(b) When the test pattern data stored in the FF 53 are supplied to the circuit block being tested, the hold violation from the test circuit to the circuit block thereof can be avoided by delaying the test pattern data by a half period of the clock signal thereof by the latch 54.

(c) When the output signal from the circuit block being tested is fetched in the FF 53 within the circuit block under test, the hold violation from the test circuit to the circuit block can be avoided by holding the output signal from the circuit block ahead a half period of the clock signal thereof by the latch 52.

Furthermore, since the FF 53 and the latches 52 and 54 are turned off during the normal operation, the power consumption thereof can be reduced.

Furthermore, since a clock skew is conventionally dealt with in a layout process of production lines, a countermeasure to a hold violation should be based on the result of the layout process thereof. In the case when the countermeasure thereto is conducted with a layout tool, etc, a device may be inserted into the path of the normal operation and the power consumption will be increased, reducing the operation speed thereof. According to this embodiment of the present invention herein, since the countermeasure to the hold violation is not necessary, the layout process can be shortened and the effects can be achieved on the power consumption and the operation speed of the normal operation.

Although the latches 52 and 54 do not include a reset function, a initial state can be set by adding a synchronous or asynchronous reset function thereto.

### Third Embodiment

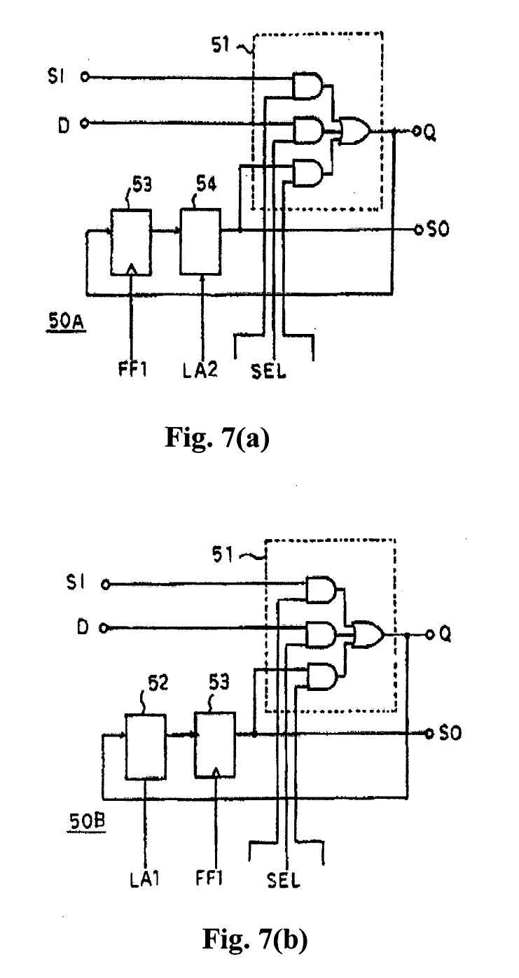

FIGS. 7(a) and 7(b) are a view of configuration diagram illustrating the scan isolation circuit according to a third embodiment of the present invention. The components that are the same as those in FIG. 4(a) are labeled with the same signs.

The scan circuit 50A in FIG. 7(a) is a circuit in which the first latch 52 is eliminated from the scan circuit isolation circuit 50₁ in FIG. 4(a). The scan circuit 50B in FIG. 7(b) is a circuit in which the second latch 54 is eliminated from the scan isolation circuit 50 in FIG. 4(a). Scan isolation circuits 50A and 50B are used instead, for example, when a clock skew problem between the circuit block and the test circuitry I and II does not exist. When the clock skew problem does not exist between the circuit block B and the test circuitry I, the scan isolation circuit 50A is used as a scan isolation circuit of the test circuitry I. When the clock skew problem does not exist between the test circuitry II and the circuit block B, the scan isolation circuit 50B of FIG. 7(b) is used as the scan isolation circuit of the test circuitry II.

Although the operation of the scan isolation circuits 50A and 50B thereof are basically the same as that of the second embodiment of the present invention, the major differences are outlined below.

(1) Scan Isolation Circuit 50A

The output signal outputted in parallel from the circuit block B by the parallel input operation is fetched in the scan isolation circuit 50A of the test circuitry I. The output signal thereof is taken to the FF 53 at the rising edge of the signal FF1 having the same timing to the clock signal CLK not through the latch thereof. The above operation becomes possible under a condition in which a clock skew problem does not exist between the circuit block B and the test circuitry I.

(2) Scan Isolation Circuit 50B

During the parallel operation, when the test pattern data stored in the scan isolation circuit 50B of the test circuitry II are supplied in parallel to the circuit block B, the test pattern data are outputted directly from the FF 53 clocked with the signal FF1 having the same timing to the clock signal CLK not through the first latch 52 thereof. The above operation becomes possible under a condition that a clock skew problem does not exist between the circuit block B and the test circuitry II.

Since the clock skew problem can be solved within the test circuitry I and II where each output terminal of the scan isolation circuit 50A and 50B is connected to the input terminal of the following circuit, the latch to deal with the clock skew problem can be eliminated.

As described before, since the latch to deal with the hold violation problem is eliminated when the scan isolation circuits 50A and 50B according to the third embodiment of the present invention are used in the circuit not having the clock skew, the area of the test circuitry can be reduced.

### Fourth Embodiment

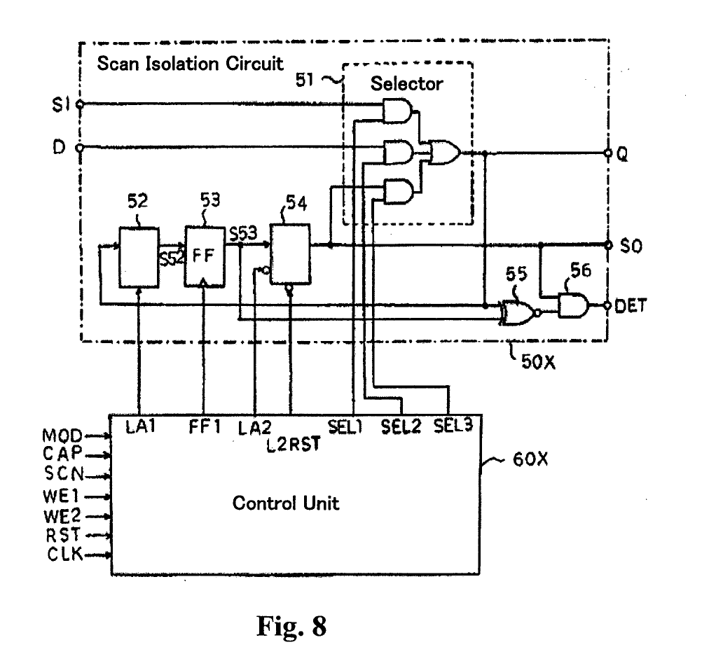

FIG. 8 is a view of a configuration diagram illustrating a test circuit according to a fourth preferred embodiment of the present invention. The components that are the same as those in FIG. 4(a) are labeled with the same signs.

The test circuit is made of a scan isolation circuit 50X corresponding to the signal between the circuit blocks therein and a control unit 60X giving a common control signal to a plurality of scan isolation circuits 50X.

The scan isolation 50X is made of a selector 51, a first latch 52, an FF 53, a second latch 54x, an EXNOR gate 55, and an AND gate 56. The latch 54x has a reset function, and is connected to the output terminal of the FF 53. The EXNOR gate 55 reverses the result of the logical exclusive OR operation between the output signal from the selector 51 and the output signal from the FF 53. The AND gate 56 performs the logical OR operation between the output signal from the EXNOR gate 55 and the output signal of the second latch 54x, and outputs the result thereof.

The control unit 60x generates selection signals SEL1-SEL3, a signal LA1, a signal FF1, and signals LA2 and L2RST. The selection signals SEL1-SEL3 control the selector 51 of the scan isolation circuit 50x. The signal LA1 controls the first latch 52. The signal FF 1 is given to the clock terminal of the FF 53. The signals LA2 and L2RST control the second latch 54x. The control unit 60x is given the control signals WE1 and WE2 and the reset signal RST, in addition to the same mode signal MOD, the same scan control signal SCN, the capture signal CAP, and the same the clock signal CLK as in FIG. 4.

The control signal WE1 is used when the signal given to the input terminal D is stored in the second latch 54x, and the control signal WE2 is used when the signal given to the input terminal D is stored in the FF 53.

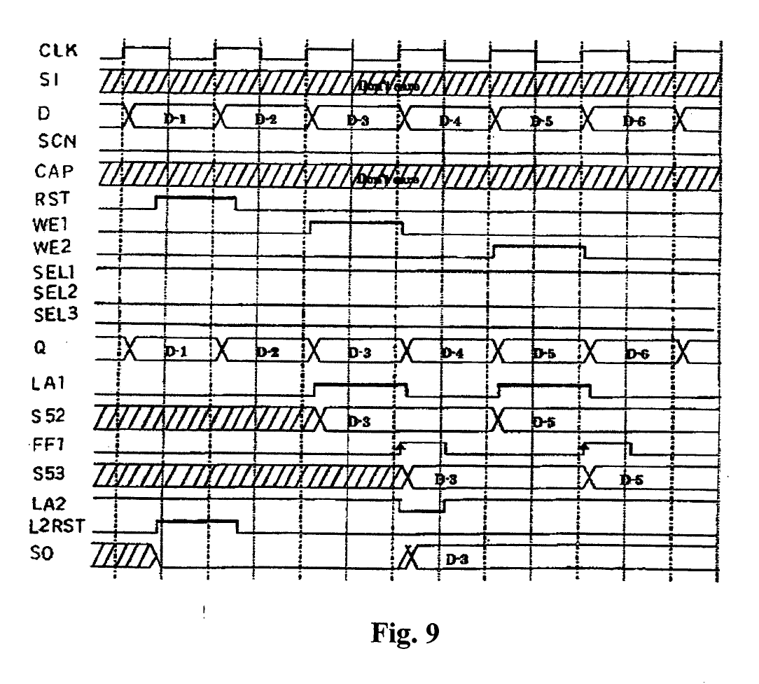

FIG. 9 is a view of a timing chart illustrating the operation during the test of FIG. 8. The operation of FIG. 8 will be explained below, also referring to FIG. 9.

First, by setting the reset signal RST given to the control 60x to active (H), the signal LA2 from the control 60x to the second latch 54x is changed to active and the signal held in the second latch 54x is reset to L.

Secondly, by setting the control signal WE1 to active, the signal given to the input terminal D of the scan isolation circuit 50x is stored in the second latch 54x through the selector 51, the first latch 52, and the FF 53.

Furthermore, by setting the control signal WE2 to active, the signal given to the input terminal D of the scan isolation circuit is stored in the FF 53 through the selector 51 and the first latch 52. At the moment, the data stored in the second latch 54x are not overwritten.

The data stored in the second latch 54x are used for the control deciding whether detecting the signal passing through the circuit blocks thereof should be conducted or not. When the data of H are stored in the second latch 54x, detection of the signal passing through the circuit blocks thereof is conducted. When the reset is done, the second latch 54x is cleared and then the aforementioned detection is not conducted.

The data stored in the FF 53 are used for the comparison of the data passing through the circuit blocks. By storing given data in FF 53 in advance, the detection of the data passing through the circuit blocks can be conducted.

For example, a test circuit of FIG. 8 is used as the circuitry I and II of the LSI of FIG. 5, where the detection position of the signal passing through the test circuitry I and II during the normal operation is decided arbitrarily and the data of H are stored in the latch 54x in order to activate the detecting function of the test circuit set for the signal under detection.

Secondly, the comparison data are stored in the FF 53 using the control signal WE2 for the test circuit set for the detection target in order to conduct the data comparison therein. By the above operation, the detection signal of H is outputted from the detecting terminal DET when the data passing through between circuit block A and B matches the data set in the FF 53.

The detection signal can be used when the circuit block is temporary halted and the current status of the circuit block is checked and so on. Furthermore, when given data are detected among a plurality of signals in a data bus and so on, the data can be detected by performing a logical OR operation between the signals from each test circuit.

As explained before, according to the fourth embodiment of the present invention, the EXNOR 55 and the detection terminal DET outputting the detection signal when the signal passing through between the circuit blocks during the normal operation are included therein.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

The term “configured” as used herein to describe a component, section or part of a device includes hardware and/or software that is constructed and/or programmed to carry out the desired function.

Moreover, terms that are expressed as “means-plus function” in the claims should include any structure that can be utilized to carry out the function of that part of the present invention.

The terms of degree such as “substantially,” “about,” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

This application claims priority to the corresponding Japanese Patent Application, the entire disclosure of which is hereby incorporated herein by reference.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

1. A integrated semiconductor circuit comprising:
a first circuit block;
a second circuit block; and
a scan isolation circuit being configured to transfer signals between said first circuit block and said second circuit block during a normal operation and to isolate said first circuit block and said second circuit block from each other, said scan isolation block including,
a first holding circuit being configured to hold a signal synchronized with a clock signal,
a first selector being configured to select one signal from an output signal outputted from said first circuit block and a first test signal outputted from said holding circuit, and
said first selector being inserted between said second circuit block and said first holding circuit, and
an output of said first selector being inputted to said first holding circuit.

2. The semiconductor circuit according to claim 1, further comprising a second scan isolation circuit that has,
a second holding circuit configured to hold a signal that is synchronized with a clock signal,
a second selector configured to select one signal from a signal outputted from said second circuit block and a second test signal outputted from said second holding circuit, said second selector is connected between said first circuit block and said second holding circuit, and
an output from said second holding circuit is inputted from said second selector.

3. The semiconductor circuit according to claim 2, wherein said output from said second holding circuit is outputted to said first selector.

4. The semiconductor circuit according to claim 2, wherein said first scan isolation circuit and said second isolation circuit include multi-stage circuits and a first test signal from a previous-stage circuit of said first scan isolation or a second test signal from a previous-stage circuit of said second scan isolation circuit is inputted to a next-stage circuit of said first scan isolation circuit or a next-stage circuit of said second scan isolation circuit.

5. The semiconductor integrated circuit according to claim 4, wherein said first scan isolation circuit and said second scan isolation circuit include a third selector that selects an output signal from said first selector or said second selector or a test signal from a previous-stage circuit or a second test signal from a previous circuit and outputs said selected signal therein to said first holding circuit or said second holding circuit.

6. The semiconductor integrated circuit according to claim 1, wherein said first selector inputs a third test signal and selects one signal out of said third test signal and an output signal from said first circuit thereof and said first test signal outputted from said first holding circuit and outputs said one signal therein.

7. The semiconductor integrated circuit according to claim 6, wherein said first test signal is inputted to said first selector through a third holding circuit that delays an input signal by a half clock period and outputs said input signal.

8. The semiconductor integrated circuit according to claim 6, wherein said first holding circuit and said third holding circuit are controlled by a control unit thereof.

9. An LSI comprising:
a first circuit block;
a second circuit block; and
a scan isolation block comprising a first second scan isolation circuit being configured to connect said first circuit block to said second circuit block and a second scan isolation circuit being configured to connect said second circuit block to said first circuit block, said first and second scan isolation circuits respectively having,
a first holding circuit being configured to hold a signal synchronized with a clock signal,
a first selector being configured to select one signal from an output signal outputted from said first circuit block and a first test signal outputted from said holding circuit, and
said first selector being inserted between said second circuit block and said first holding circuit, and
an output of said first selector being inputted to said first holding circuit.

10. The LSI according to claim 9, wherein said first scan isolation circuits include,
a first stage first scan isolation circuit that has,
a first selector that has a first input terminal directly connected to said first circuit block, and an output terminal connected to said second circuit block,
a second selector having a first input terminal configured to receive a signal from a scan input terminal, and a second input terminal connected to said output terminal of said first selector, and
a flip-flop that has an input terminal connected to an output terminal of said second selector, and an output terminal connected to a second input terminal of said first selector, said output terminal of said flip-flop of said first stage first scan isolation circuit configured to output a signal to a subsequently staged first scan isolation circuit, and
a final stage first scan isolation circuit that has,
a first selector that has a first input terminal being directly connected to said first circuit block, and an output terminal connected to said second circuit block,
a second selector that has a first input terminal configured to receive a signal from a flip-flop of a previous stage first scan isolation circuit, and a second input terminal connected to said output terminal of said first selector, and
a flip-flop that has an input terminal connected to an output terminal of said second selector, and an output terminal connected to a second input terminal of said first selector, said output terminal of said flip-flop of said final stage first scan isolation circuit configured to output a signal.

11. The LSI according to claim 10, wherein said second scan isolation circuits include,
a first stage second scan isolation circuit that has,
a first selector that has a first input terminal directly connected to said second circuit block, and an output terminal connected to said first circuit block,
a second selector that has a first input terminal configured to receive a signal from said scan input terminal, and a second input terminal connected to said output terminal of said first selector, and
a flip-flop that has an input terminal connected to an output terminal of said second selector, and an output terminal connected to a second input terminal of said first selector, said output terminal of said flip-flop of said first stage second scan isolation circuit configured to output a signal to a subsequently staged second scan isolation circuit, and
a final stage second scan isolation circuit that has,
a first selector that has a first input terminal directly connected to said second circuit block, and an output terminal connected to said first circuit block,
a second selector that has a first input terminal configured to receive a signal from a flip-flop of a previous stage second scan isolation circuit, and a second input terminal connected to said output terminal of said first selector, and
a flip-flop that has an input terminal connected to an output terminal of said second selector, and an output terminal connected to a second input terminal of said first selector, said output terminal of said flip-flop of said final stage first scan isolation circuit configured to output a signal.

12. The LSI according to claim 9, further comprising a control unit that gives common control signals to at least one of said first and second isolation circuits, wherein each of said first and second scan isolation circuits comprise,
a selector configured to select and to output a signal received from within said first or second scan isolation circuit, from said control unit, or from outside said first or second scan isolation circuit and said control unit,
a first latch connected to an output terminal of said selector,
a flip-flop connected to an output terminal of said first latch, and
a second latch connected to an output terminal of said flip-flop, said second latch configured to provide a signal to said selector.

13. The LSI according to claim 9, wherein said first and second scan isolation circuits further include,
an EXNOR gate connected to said output terminal of said flip-flop and said output terminal of said selector, and
an AND gate connected to an output terminal of said EXNOR gate and an output terminal of said second latch.

14. The LSI according to claim 13,wherein said first and second scan isolation circuits further comprise a detecting terminal, wherein said AND is configured to output a detection signal from said detecting terminal.

15. The LSI according to claim 9, further comprising a control unit that gives common control signals to at least one of said first and second isolation circuits, wherein at least one of said first and second scan isolation circuits comprise,
a selector configured to select and to output a signal received from within said first or second scan isolation circuit, from said control unit, or from outside said first or second scan isolation circuit and said control unit,
a latch connected to an output terminal of said selector, and
a flip-flop connected to an output terminal of said latch, said flip-flop configured to provide a signal to said selector.

16. The LSI according to claim 9, further comprising a control unit that gives common control signals to at least one of said first and second isolation circuits, wherein at least one of said first and second scan isolation circuits comprise,
a selector configured to select and to output a signal received from within said first or second scan isolation circuit, from said control unit, or from outside said first or second scan isolation circuit and said control unit,
a flip-flop connected to an output terminal of said selector, and
a latch connected to an output terminal of said flip-flop, said latch configured to provide a signal to said selector.

17. The LSI according to claim 9, further comprising a second scan isolation circuit that has,
a second holding circuit configured to hold a signal that is synchronized with a clock signal,
a second selector configured to select one signal from a signal outputted from said second circuit block and a second test signal outputted from said second holding circuit, said second selector is connected between said first circuit block and said second holding circuit, and
an output from said second holding circuit is inputted from said second selector.

18. The LSI according to claim 17, wherein said output from said second holding circuit is outputted to said first selector.

19. The LSI according to claim 17, wherein said first scan isolation circuit and said second isolation circuit include multi-stage circuits and a first test signal from a previous-stage circuit of said first scan isolation or a second test signal from a previous-stage circuit of said second scan isolation circuit is inputted to a next-stage circuit of said first scan isolation circuit or a next-stage circuit of said second scan isolation circuit.

20. The LSI according to claim 19, wherein said first scan isolation circuit and said second scan isolation circuit include a third selector that selects an output signal from said first selector or said second selector or a test signal from a previous-stage circuit or a second test signal from a previous circuit and outputs said selected signal therein to said first holding circuit or said second holding circuit.
